(19) United States
(12) Patent Application Publication
(10) Pub. No.: US 2011/0061904 A1
(43) Pub. Date: Mar. 17, 2011

(54) Display array substrate and method of manufacturing display substrate

(75) Inventors: Woon Chun Kim, Suwon (KR); Hyun Seop Shim, Incheon (KR); Soon Gyu Yim, Seongnam (KR); Jong Young Lee, Suwon (KR)

(73) Assignee: SAMSUNG ELECTRO MECHANICS CO., LTD., Suwon (KR)

(21) Appl. No.: 12/654,369

(22) Filed: Dec. 17, 2009

(30) Foreign Application Priority Data
Sep. 15, 2009 (KR) 10-2009-0087089

(51) Int. Cl. H05K 1/03; B26D 3/06; B26D 9/00

(52) U.S. Cl. 174/255; 83/875; 83/39

(57) ABSTRACT

A display array substrate according to an aspect of the invention may include: a substrate wafer having cutting grooves curved inward; and a transparent electrode coated over one surface of the substrate wafer, wherein shock, occurring when cutting the substrate wafer, is prevented from being transmitted to the transparent electrode by cutting the substrate wafer along the cutting grooves having a different height from the transparent electrode.

### CROSS-REFERENCE TO RELATED APPLICATIONS

This application claims the priority of Korean Patent Application No. 10-2009-0087089 filed on Sep. 15, 2009, in the Korean Intellectual Property Office, the disclosure of which is incorporated herein by reference.

### BACKGROUND OF THE INVENTION

1. Field of the Invention

The present invention relates to a display array substrate and a method of manufacturing the same, and more particularly, to a substrate in which substrates, applied to a display device, are arrayed, and a method of manufacturing substrate parts by cutting this array substrate.

2. Description of the Related Art

Recently, touch type personal portable devices detect whether a user touches display devices, and the entire devices vibrate according to a detection result indicating the user has touched the display devices.

Here, touch type display devices mean input devices that detect a contact position at which a user touches the surface of the display device, and perform the general control of an electronic device, including a display screen control on the basis of information on the detected contact position as input information.

The touch type display devices further include vibration elements providing a feedback through vibrations with respect to a touch made when a user touches the display devices. These vibration elements may be arranged on the edge of the display devices.

These touch type display devices may be divided into resistive overlay touch display devices and capacitive overlay touch display devices. In particular, capacitive overlay touch display devices that detect a contact position on the basis of changes in capacitance caused by a user's contact applied to a front face of a display window have been gradually used in a wide range of applications because of high durability and suitability for sliding-type inputs.

In these capacitive overlay display devices, transparent electrodes are provided on display substrates in order to detect changes in the capacitance. In order to manufacture these display substrates, a large-sized display array substrate is prepared and is cut into unit display substrates.

However, when the display array substrate is cut into the unit display substrates, forces generated during the cutting operation cause cracks around the transparent electrodes provided in the display substrates or delaminations around the cutting surfaces. Therefore, there is a need for techniques to solve these problems.

### SUMMARY OF THE INVENTION

An aspect of the present invention provides a display array substrate and a method of manufacturing a display substrate that can prevent delaminations or cracks in a transparent electrode.

According to an aspect of the present invention, there is provided a display array substrate including: a substrate wafer having cutting grooves curved inward; and a transparent electrode coated over one surface of the substrate wafer, wherein shock, occurring when cutting the substrate wafer, is prevented from being transmitted to the transparent electrode by cutting the substrate wafer along the cutting grooves having a different height from the transparent electrode.

The cutting grooves may be provided in both surfaces of the substrate wafer.

The transparent electrode may include transparent electrodes coated over both surfaces of the substrate wafer.

The transparent electrode may be coated over one surface of the substrate wafer having the cutting grooves therein.

The transparent electrode may use at least one of ceramics, conductive polymer or a mixture containing carbon.

According to another aspect of the present invention, there is provided a method of manufacturing a display substrate, the method including: forming cutting grooves in one surface of a substrate wafer having a plurality of substrate parts, formed in a single body, in units of the substrate parts; forming a transparent electrode on the one surface of the substrate wafer; and cutting the array substrate along the cutting groves to manufacture the substrate parts having a predetermined size.

In the forming of the cutting grooves, the substrate wafer may pass through a roller having protrusions from an outer surface thereof to form cutting grooves in the substrate wafer.

In the forming of the cutting grooves, rollers having protrusions from outer surfaces thereof may be arranged to face each other, and the substrate wafer passes between the rollers to form cutting grooves in both surfaces of the substrate wafer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view illustrating a personal portable device to which a display substrate is applied according to an exemplary embodiment of the present invention;

FIG. 2 is a cross-sectional view illustrating the operating principle of the display substrate of FIG. 1;

FIGS. 3 through 5 are cross-sectional views and front views illustrating a display array substrate and a method of manufacturing display substrates from the display array substrate;

FIG. 6 is a side view illustrating a method of forming cutting grooves in a display array substrate according to an exemplary embodiment of the present invention;

FIGS. 7A through 7C are cross-sectional views and front views illustrating a display array substrate and a method of manufacturing the same according to another exemplary embodiment of the present invention;

FIGS. 8A through 8C are cross-sectional views and front views illustrating a display array substrate and a method of manufacturing the same according to another exemplary embodiment of the present invention; and

FIGS. 9A through 9C are cross-sectional views and front views illustrating a display array substrate and a method of manufacturing the same according to another exemplary embodiment of the present invention.

### DETAILED DESCRIPTION OF THE PREFERRED EMBODIMENT

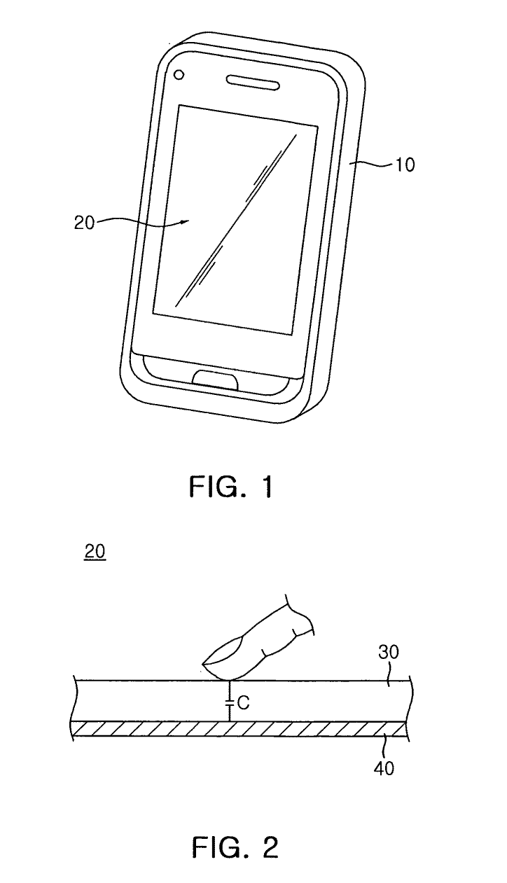

A display array substrate and a method of manufacturing a display substrate will be described in detail with reference to FIGS. 1 through 9. Exemplary embodiments of the present invention will now be described in detail with reference to the accompanying drawings.

The invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, the shapes and dimensions may be exaggerated for clarity, and the same reference numerals will be used throughout to designate the same or like components.

FIG. 1 is a perspective view illustrating a personal portable device to which a display substrate is applied according to an exemplary embodiment of the invention. FIG. 2 is a cross-sectional view illustrating the operating principle of the display substrate of FIG. 1.

Referring to FIGS. 1 and 2, a display substrate 20 may be mounted onto a display device that is formed on an entire surface of a personal portable device 10, and may the above-described touch type display substrate.

The display substrate 20 may include a substrate part 30, a transparent electrode 40 and a piezoelectric actuator (not shown).

The substrate part 30 is mounted onto the entire surface of the personal portable device 10 and may be formed of transparent materials such as reinforced glass or acryl uniform in thickness or dielectric constant.

The transparent electrode 40 is formed on one surface of the substrate part 30. As shown in FIG. 2, the transparent electrode 40 detects changes in capacitance on the substrate part 30. Therefore, when a user's body part, for example, the user's finger tips make contact with the substrate part 30 at a specific position, a change occurs in capacitance C formed between the transparent electrode 40 at the corresponding position and the contact surface of the body. On the basis of data about the change in the capacitance C, a control unit calculates the X-direction and Y-direction components of a contact position.

The transparent electrode 40 may be formed of at least one of ceramics, conductive polymer or a mixture containing carbon.

The piezoelectric actuator (not shown) may be designed to be driven according to a contact signal, and may be arranged at the side of the substrate part 30. However, the position of the piezoelectric actuator is not limited thereto, and may vary according to the designers' intentions.

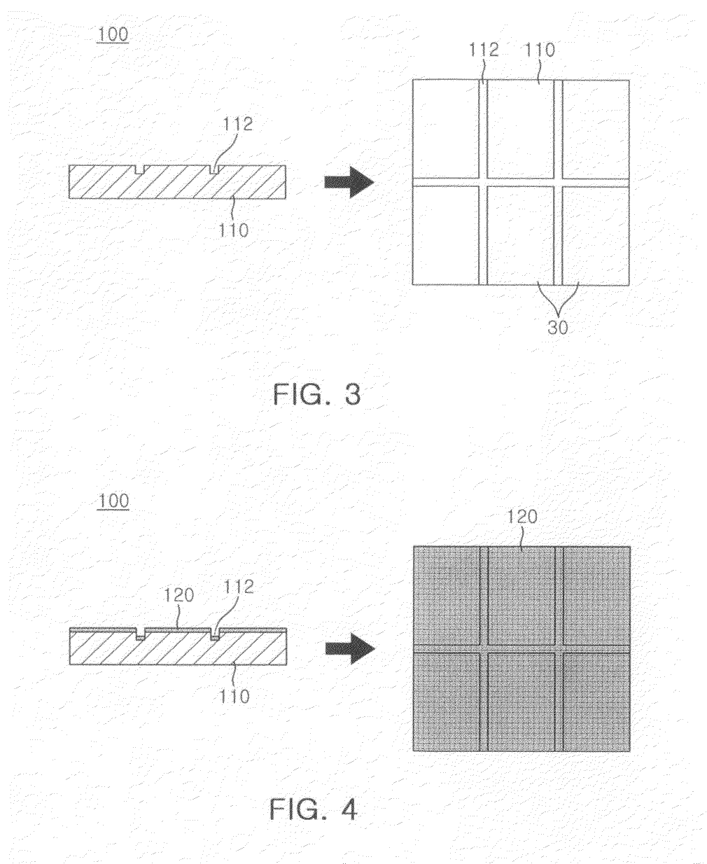

FIGS. 3 through 5 are cross-sectional views and front views illustrating a display array substrate and a method of manufacturing display substrates from the display array substrate according to an exemplary embodiment of the invention.

Referring to FIG. 3 through 5, a display array substrate 100 includes a substrate wafer 110 and a transparent electrode 120.

The substrate wafer 110 has a plurality of substrate part 30 formed in a single body, which can be applied to personal portable devices. The substrate wafer 110 has a large size so that the substrate wafer 110 is cut to substrate part 30 size.

Here, cutting grooves 112, which are curved inward, may be provided in one surface of the substrate wafer 110. Here, the cutting grooves 112 may be formed to define the outlines of the substrate parts 30 so that each block defined by the cutting grooves corresponds to the substrate part size.

The substrate wafer 110 may be formed of transparent materials such as reinforced glass or acryl uniform in thickness or dielectric constant.

The transparent electrode 120 may be coated over one surface of the substrate wafer 110. Here, the one surface may refer to a surface in which the cutting grooves 112 are formed. Here, the transparent electrode 120 is also formed on one surface of each of the cutting grooves 112.

Here, the cutting grooves 112 have a rectangular shape in cross-section. However, the invention is not limited thereto, and the cutting grooves 112 may have a circular shape in cross-section.

The transparent electrode 120 may be formed of at least one of ceramics, conductive polymer or a mixture containing carbon. Here, the conductive polymer may be polythiophene (PEDOT) or polyaniline, the ceramics may be ITO, IZO, AZO, GZO, FTO or ZnO, and the mixture containing carbon may be CNT, graphene or carbon black.

Therefore, in order to manufacture the substrate parts 30, the substrate wafer 110 is cut along the cutting grooves 112. Here, the substrate wafer 110 is cut along the cutting grooves 112 having a different height from the transparent electrode 120, thereby preventing shock, occurring when cutting the substrate wafer 10, from being directly transmitted to the transparent electrode 120.

A method of manufacturing a display substrate will now be described.

Firs, as shown in FIG. 3, according to the method of manufacturing a display substrate, the cutting grooves 112 are formed in one surface of the substrate wafer 110 having the plurality of substrate parts 30 formed in a single body to define the individual substrate parts 30.

Then, as shown in FIG. 4, the transparent electrode 120 may be formed on the one surface of the substrate wafer 110 in which the cutting grooves 112 are formed.

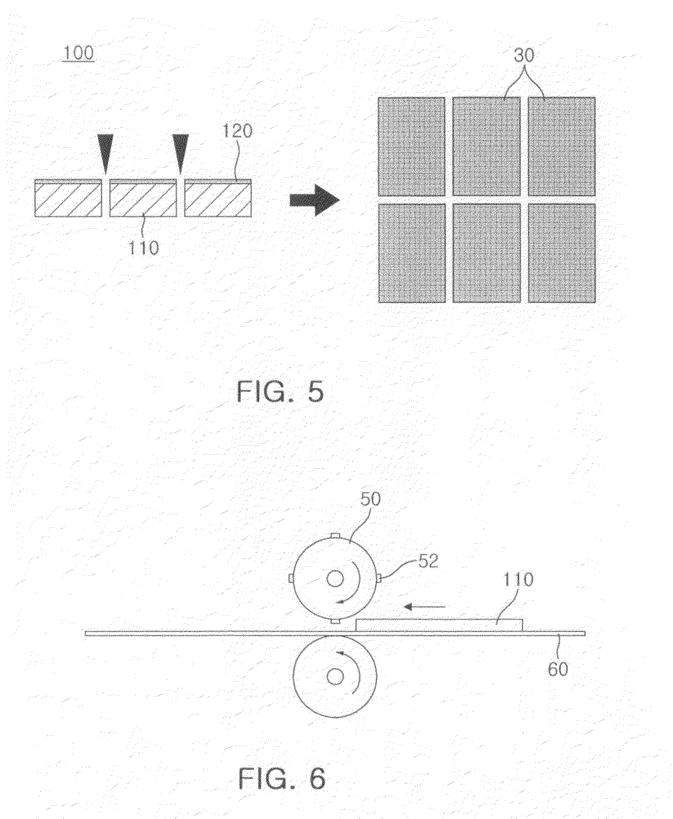

As shown in FIG. 5, the substrate wafer 110 is cut along the cutting grooves 112 in order to manufacture substrates having a predetermined size.

After the transparent electrode 120 is formed on the substrate wafer 110 in which the cutting grooves 112 are not formed, if the substrate wafer 110 is cut to the substrate part 30 size, delaminations or cracks of the transparent electrode 120 may occur around the cutting surfaces.

However, according to the display array substrate and the method of manufacturing a display substrate according to the embodiments of the invention, since the cutting grooves 112, which are curved inward, are formed in the substrate wafer 110, there is a height difference between the surfaces of the cutting grooves 112 and the substrate parts 30. Furthermore, shock, occurring when the substrate wafer 110 is cut along the cutting grooves 112, can be prevented from being directly transmitted to the transparent electrode formed on the surface of the substrate parts 30. As a result, the durability of the display substrate can be increased.

FIG. 6 is a side view illustrating a method of forming cutting grooves in a display array substrate according to an exemplary embodiment of the invention.

Referring to FIG. 6, when the cutting grooves 112 are formed according to the method of manufacturing a display substrate, as the substrate wafer 110 passes between rollers 50 having protrusions 52 from outer surfaces thereof, the cutting grooves 112 are formed in the substrate wafer 110.

Here, the positions at which the protrusions 52 are formed on the rollers 50 may vary according to intervals of the cutting grooves 112 formed in the substrate wafer 110.

Therefore, when the substrate wafer 110 is automatically moved along a transfer device 60 in a direction toward the rollers 50 (arrow direction), the substrate wafer 110 and the protrusions 52 make contact with each other, whereby the cutting grooves 112 are formed in the substrate wafer 110.

Therefore, an operator does not need to separately and individually form the cutting grooves 112 in the substrate wafer 110. Through these processes, the cutting grooves 112 are automatically and continuously formed, thereby simplifying a manufacturing process and reducing manufacturing time.

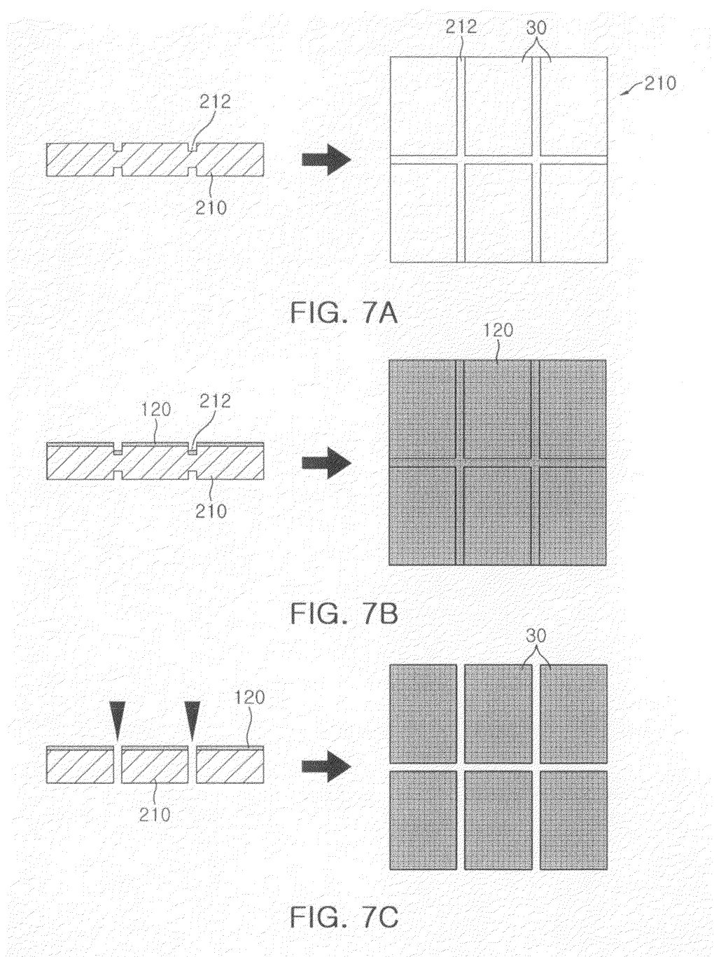

FIGS. 7A through 7C are cross-sectional views and front views illustrating a display array substrate and a method of manufacturing the substrate according to another exemplary embodiment of the invention.

First, as shown in FIG. 7A, according to a method of manufacturing a display substrate according to this embodiment, cutting grooves 212 are formed in both surfaces of substrate wafer 210 having the plurality of substrate part 30, formed in a single body, to thereby define the substrate parts 30.

Here, the cutting grooves 212 can be formed in both surfaces of the substrate wafer 210 at the same time by arranging rollers having protrusions thereon at both sides and passing the substrate wafer 210 between the rollers arranged at both sides.

As shown in FIG. 7B, the transparent electrode 120 may be formed on one surface of the substrate wafer 110 in which the cutting grooves 212 are formed.

Then, as shown in FIG. 7C, in order to manufacture substrates having a predetermined size, the substrate wafer 210 is cut along the cutting grooves 212 to thereby manufacture the plurality of substrate parts 30.

Therefore, in this embodiment, since the cutting grooves 212 are formed in both surfaces of the substrate wafer 210, the substrate wafer 210 has a relatively smaller thickness at positions corresponding to the cutting grooves 212, thereby facilitating the cutting operation.

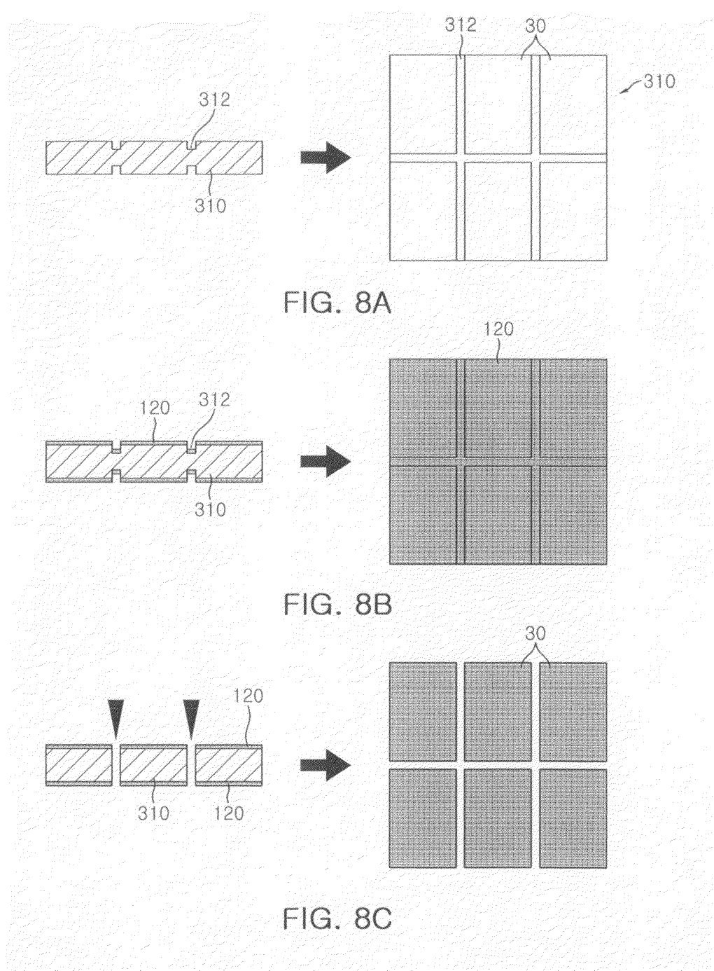

FIGS. 8A through 8C are cross-sectional views and front views illustrating a display array substrate and a method of manufacturing the substrate according to another exemplary embodiment of the invention.

First, as shown in FIG. 8A, according to the method of manufacturing a display substrate, cutting grooves 312 may be formed in both surfaces of a substrate wafer 310 having substrate parts 30, formed in a single body, to define the individual substrate parts 30.

Here, the cutting grooves 312 can be formed in both surfaces of the substrate wafer 310 at the same time by passing the substrate wafer 310 between the above-described rollers.

Then, as shown in FIG. 8B, the transparent electrodes 120 may be formed on both surfaces of the substrate wafer 310 in which the cutting grooves 312 are formed.

Further, as shown in FIG. 8C, in order to manufacture substrates having a predetermined size, the substrate wafer 310 is cut along the cutting grooves 312 to thereby manufacture the plurality of substrate part 30.

Therefore, in this case, the transparent electrodes 120 may be formed on both surfaces of the substrate part 30.

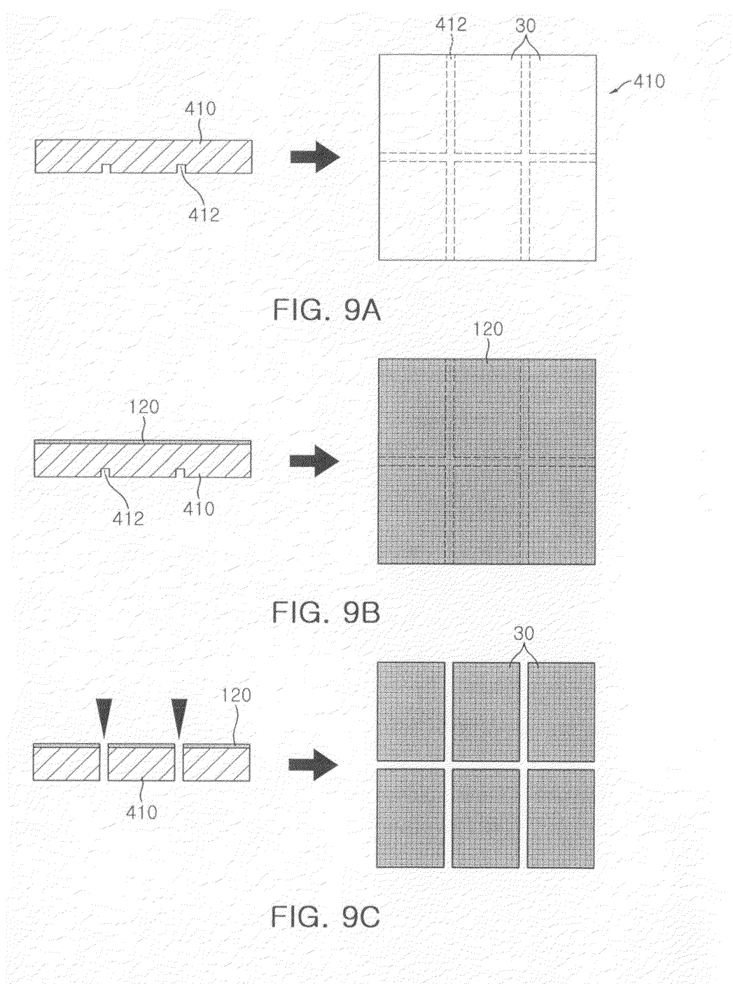

FIGS. 9A through 9C are cross-sectional views and front views illustrating a display array substrate and a method of manufacturing the same according to another exemplary embodiment of the invention.

First, as shown in FIG. 9A, according to the method of manufacturing a display substrate according to this embodiment, cutting grooves 412 are formed in a lower surface of a substrate wafer 410 having the plurality of substrate parts 30, formed in a single body, to define the outlines of substrate parts 30.

Then, as shown in FIG. 9B, the transparent electrode 120 may formed on the other surface opposite to one surface of the substrate wafer 410, in which the cutting grooves 412 are formed.

Then, as shown in FIG. 9C, in order to manufacture substrates having a predetermined size, the substrate wafer 410 is cut along the cutting grooves 412 to thereby manufacture the plurality of substrate part 30.

Therefore, since the substrate wafer 410 has a smaller thickness at positions where the cutting grooves 412 are formed than other portions of the substrate wafer 410, even when a relatively smaller force is applied, the substrate wafer 410 can be cut along the cutting grooves 412.

As set forth above, according to exemplary embodiments of the invention, a display array substrate and a method of manufacturing a display substrate form cutting groves curved inward in a substrate wafer, so that shock, occurring when the substrate wafer is cut along the cutting grooves to manufacture display substrates, can be prevented from being directly transmitted to a transparent electrode, thereby increasing the durability of the display substrates.

While the present invention has been shown and described in connection with the exemplary embodiments, it will be apparent to those skilled in the art that modifications and variations can be made without departing from the spirit and scope of the invention as defined by the appended claims.

What is claimed is:

1. A display array substrate comprising:
a substrate wafer having cutting grooves curved inward; and
a transparent electrode coated over one surface of the substrate wafer,
wherein shock, occurring when cutting the substrate wafer, is prevented from being transmitted to the transparent electrode by cutting the substrate wafer along the cutting grooves having a different height from the transparent electrode.

2. The display array substrate of claim 1, wherein the cutting grooves are provided in both surfaces of the substrate wafer.

3. The display array substrate of claim 1, wherein the transparent electrode comprises transparent electrodes coated over both surfaces of the substrate wafer.

4. The display array substrate of claim 1, wherein the transparent electrode is coated over one surface of the substrate wafer having the cutting grooves therein.

5. The display array substrate of claim 1, wherein the transparent electrode uses at least one of ceramics, conductive polymer or a mixture containing carbon.

6. A method of manufacturing a display substrate, the method comprising:
forming cutting grooves in one surface of a substrate wafer having a plurality of substrate parts, formed in a single body, in units of the substrate parts;
forming a transparent electrode on the one surface of the substrate wafer; and
cutting the array substrate along the cutting groves to manufacture the substrate parts having a predetermined size.

7. The method of claim 6, wherein in the forming of the cutting grooves, the substrate wafer passes through a roller having protrusions from an outer surface thereof to form cutting grooves in the substrate wafer.

8. The method of claim 6, wherein in the forming of the cutting grooves, rollers having protrusions from outer surfaces thereof are arranged to face each other, and the substrate wafer passes between the rollers to form cutting grooves in both surfaces of the substrate wafer.
